(19) United States
(12) Patent Application Publication
(10) Pub. No.: US 2025/0393140 A1
(43) Pub. Date: Dec. 25, 2025

(54) PROTECTIVE COVER FOR ACCESS CONTROL WITH INTEGRATED NOTIFICATION SYSTEM

(71) Applicant: PRIMARY ALERT SYSTEMS, LLC, Owosso, MI (US)

(72) Inventor: Christopher Carpenter, Owosso, MI (US)

(21) Appl. No.: 19/244,779

(22) Filed: Jun. 20, 2025

Related U.S. Application Data
(60) Provisional application No. 63/662,918, filed on Jun. 21, 2024.

(51) Int. Cl. H05K 5/02; G06F 1/16

(52) U.S. Cl. CPC H05K 5/0208; G06F 1/1677

(57) ABSTRACT

A protective device, system, and method are disclosed. The protective device is designed to enhance the security of an object or place by safeguarding the access control. The protective device may generally include a cover configured to surround the access control. The cover may include a frame with a cover or the cover may be a magnetic cover. The protective device may include a sensor disposed on an inside portion of the cover. The sensor may be configured to send an alert to the user when the access control is exposed, when the cover is tampered with, and when the cover is moving from the closed position to the open position.

### CROSS-REFERENCE TO RELATED APPLICATIONS

This application claims the benefit of U.S. Provisional Application No. 63/662,918, filed on Jun. 21, 2024. The entire disclosure of the above application is incorporated herein by reference.

### FIELD

The present technology relates to security devices and, more particularly, to enhancements in protective measures for access control of an object or place.

### INTRODUCTION

This section provides background information related to the present disclosure which is not necessarily prior art.

A keypad or access control may be used to secure a valuable item, ranging from personal belongings, access to a location, such as a gate lock and an access to sensitive documents. The object or location may be equipped with various forms of access control, such as a keypad or biometric sensor, which are designed to restrict access. While these mechanisms may be effective in controlling access, such mechanisms may be left exposed and vulnerable to tampering or unauthorized attempts to gain entry. An exposed access control may pose a security risk and also leave an area or object susceptible to damage or manipulation of the access mechanism.

There may also be no way to provide a real-time notification specifically focused on the interaction with an access control. While general notification of a successful attempt to access a control, there is a lack of a specific alert system that may inform a user of when the access control may be physically interacted with or opened. Accordingly, there is a continuing need for an improved protective measure for access control of an area and/or a device. Desirably, such protective measure would shield the access control from tampering and unauthorized access while allowing user interaction and providing real-time notification regarding the status of the protective measure itself.

### SUMMARY

In concordance with the instant disclosure, a protective measure for the access control that shields an access control from unauthorized access while allowing for selective user interaction and providing real-time notification regarding the status of the protective measure itself, has surprisingly been discovered.

The present technology includes articles of manufacture, systems, and processes that relate to the use of a protective cover to safeguard an access control while enabling selective user interaction and real-time notification capabilities.

In certain embodiments, a protective device for safeguarding an access control of an object may include a frame, a cover, and a sensor. The frame may include a sidewall configured to surround the access control of the object. The cover may be movably connected to the frame, while the sensor may be configured to detect a movement of the cover. The sensor may be in communication with a notification mechanism, where the notification mechanism may be configured to send a notification to a user device when the cover is moved.

In certain embodiments, a protective cover system may include a body defining a container including an access control of an object comprising a frame having a sidewall configured to surround the access control of the object and a cover movably connected to the frame. A sensor may be coupled to the frame. The sensor may be configured to detect a movement of the cover and be in communication with a notification mechanism. The notification mechanism may be configured to send a notification to a user device when the cover is moved.

In still certain embodiments, a method of safeguarding an access control of a device may include providing a device having a body defining a container. The body may include the access control disposed on an outer portion of the body. The method may further include providing a cover for the access control, and sending a notification to a user device when the cover is moved from a closed position to an open position.

### DRAWINGS

The drawings described herein are for illustrative purposes only of selected embodiments and not all possible implementations, and are not intended to limit the scope of the present disclosure.

FIG. 1 is a block diagram illustrating a protective device, according to an embodiment of the present disclosure.

FIG. 2 is a prospective illustration of a front cover of a protective cover system, according to an embodiment of the present disclosure.

FIG. 3 is a prospective illustration of a back of a cover of a protective cover system, according to an embodiment of the present disclosure.

FIG. 4 is a prospective illustration of a back of a cover of a protective cover system, according to an embodiment of the present disclosure.

FIG. 5 is a prospective illustration of a back of a cover of a protective cover system, according to an embodiment of the present disclosure.

FIG. 6 is a prospective illustration of a front cover of a protective cover system, according to another embodiment of the present disclosure.

FIG. 7 is a prospective illustration of a back of a cover of a protective cover system, according to another embodiment of the present disclosure.

FIG. 8 is a prospective illustration of a back of a cover of a protective cover system, according to another embodiment of the present disclosure.

FIG. 9 is a view illustrating the protective device mounted over an access control of an object, according to an embodiment of the present disclosure.

FIG. 10 is a view illustrating the protective device mounted over an access control of an object safe, as shown in FIG. 9, with the cover advancing from the closed position to an open position.

FIG. 11 is a view illustrating the protective device mounted over an access control of an object, according to an embodiment of the present disclosure.

FIG. 12 is a view illustrating the protective device mounted over an access control of an object safe, as shown in FIG. 11, with the cover advancing from the closed position to an open position.

FIG. 13 is a flowchart of a method of safeguarding an access control of a safe, according to yet another embodiment of the present disclosure.

### DETAILED DESCRIPTION

The following description of technology is merely exemplary in nature of the subject matter, manufacture and use of one or more inventions, and is not intended to limit the scope, application, or uses of any specific invention claimed in this application or in such other applications as may be filed claiming priority to this application, or patents issuing therefrom. Regarding methods disclosed, the order of the steps presented is exemplary in nature, and thus, the order of the steps can be different in various embodiments, including where certain steps can be simultaneously performed, unless expressly stated otherwise. “A” and “an” as used herein indicate “at least one” of the item is present; a plurality of such items may be present, when possible. Except where otherwise expressly indicated, all numerical quantities in this description are to be understood as modified by the word “about” and all geometric and spatial descriptors are to be understood as modified by the word “substantially” in describing the broadest scope of the technology. “About” when applied to numerical values indicates that the calculation or the measurement allows some slight imprecision in the value (with some approach to exactness in the value; approximately or reasonably close to the value; nearly). If, for some reason, the imprecision provided by “about” and/or “substantially” is not otherwise understood in the art with this ordinary meaning, then “about” and/or “substantially” as used herein indicates at least variations that may arise from ordinary methods of measuring or using such parameters.

Although the open-ended term “comprising,” as a synonym of non-restrictive terms such as including, containing, or having, is used herein to describe and claim embodiments of the present technology, embodiments may alternatively be described using more limiting terms such as “consisting of” or “consisting essentially of.” Thus, for any given embodiment reciting materials, components, or process steps, the present technology also specifically includes embodiments consisting of, or consisting essentially of, such materials, components, or process steps excluding additional materials, components or processes (for consisting of) and excluding additional materials, components or processes affecting the significant properties of the embodiment (for consisting essentially of), even though such additional materials, components or processes are not explicitly recited in this application. For example, recitation of a composition or process reciting elements A, B and C specifically envisions embodiments consisting of, and consisting essentially of, A, B and C, excluding an element D that may be recited in the art, even though element D is not explicitly described as being excluded herein.

As referred to herein, disclosures of ranges are, unless specified otherwise, inclusive of endpoints and include all distinct values and further divided ranges within the entire range. Thus, for example, a range of “from A to B” or “from about A to about B” is inclusive of A and of B. Disclosure of values and ranges of values for specific parameters (such as amounts, weight percentages, etc.) are not exclusive of other values and ranges of values useful herein. It is envisioned that two or more specific exemplified values for a given parameter may define endpoints for a range of values that may be claimed for the parameter. For example, if Parameter X is exemplified herein to have value A and also exemplified to have value Z, it is envisioned that Parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if Parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, 3-9, and so on.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

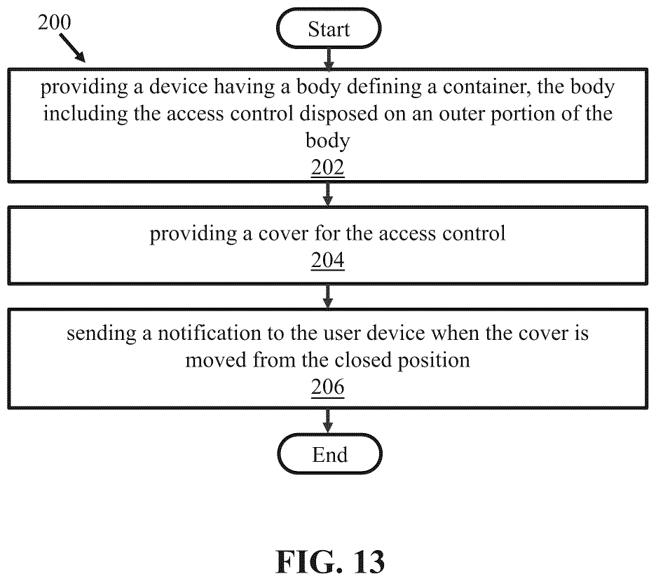

The present technology improves the security and functionality of an object such as a safe, a gate, or other place and/or object that may need to be accessed by providing a protective device 100 that safeguards an access control 130 of the object against tampering and access and also incorporates a real-time notification. Advantageously, the protective device 100 may allow a user to be informed when the protective device 100 is accessed, thereby militating the risk of a security breach and maintaining ease of use for an authorized user. A protective method 200, is also provided, as also shown in accompanying FIG. 13. One of ordinary skill in the art may select a suitable unit for storage to couple with the protective device 100 within the scope of the present disclosure. This may further include access to a place such as a gate, a storage area, building, room, or fenced in area, or other appropriately desired space, where an access control, lock box, key storage or other appropriately desired secured mechanism may be located.

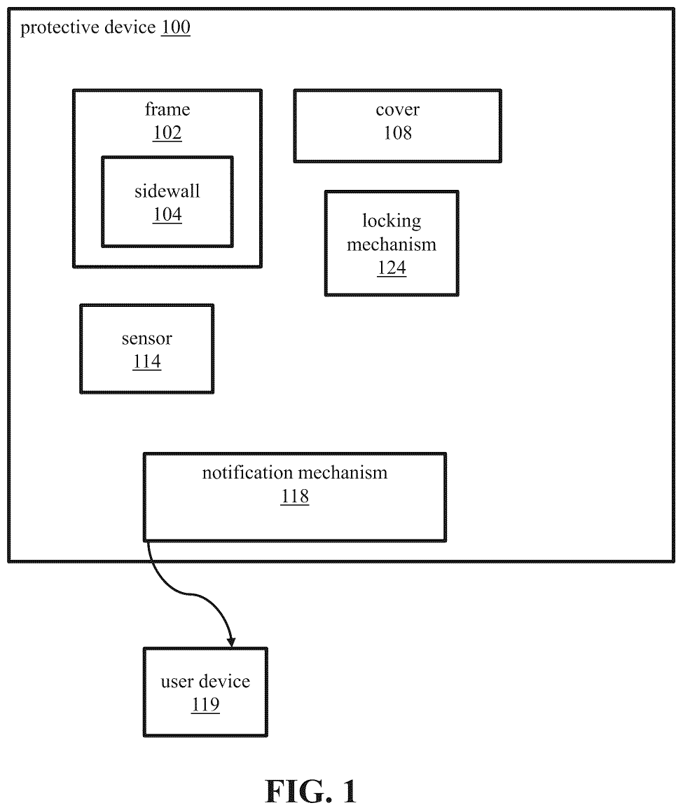

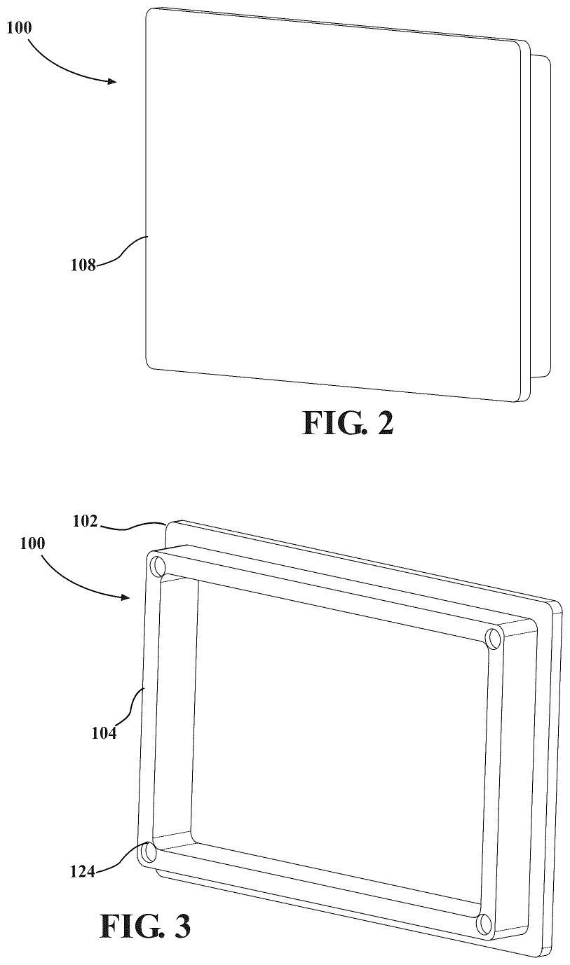

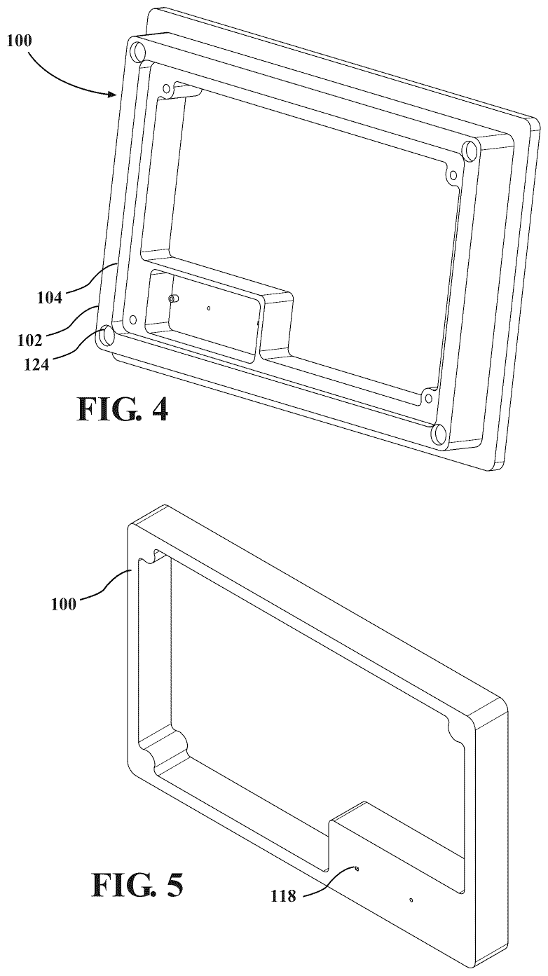

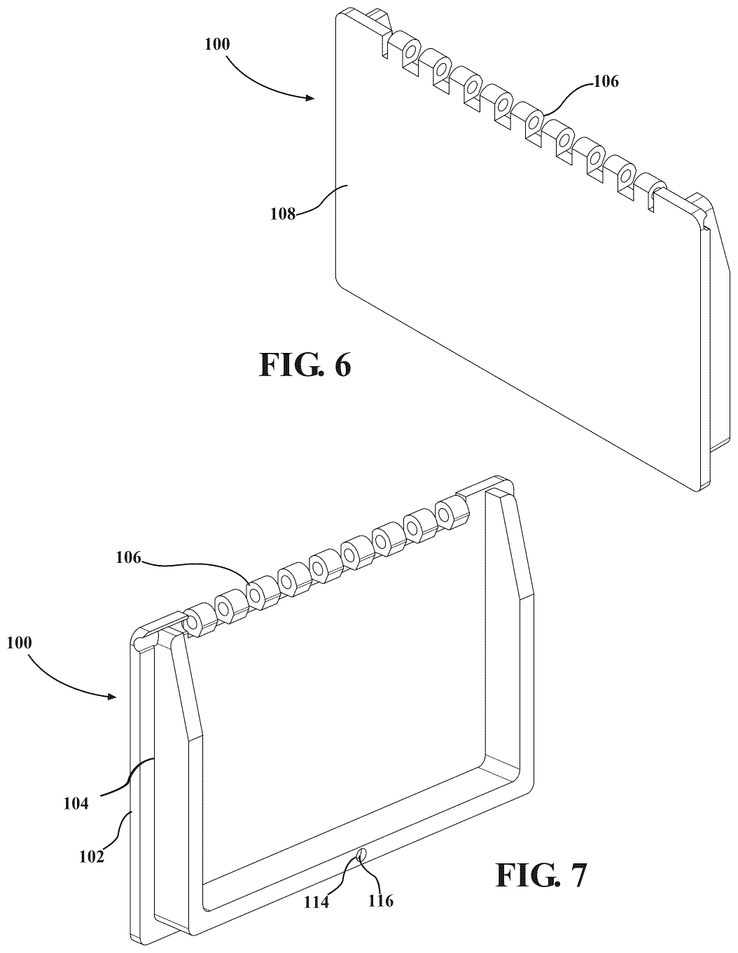

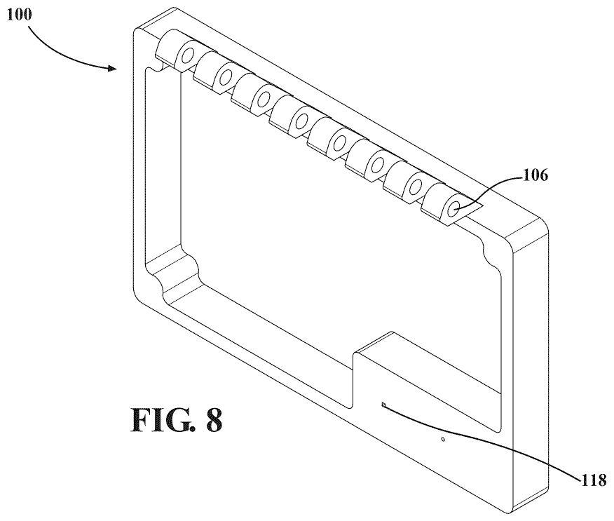

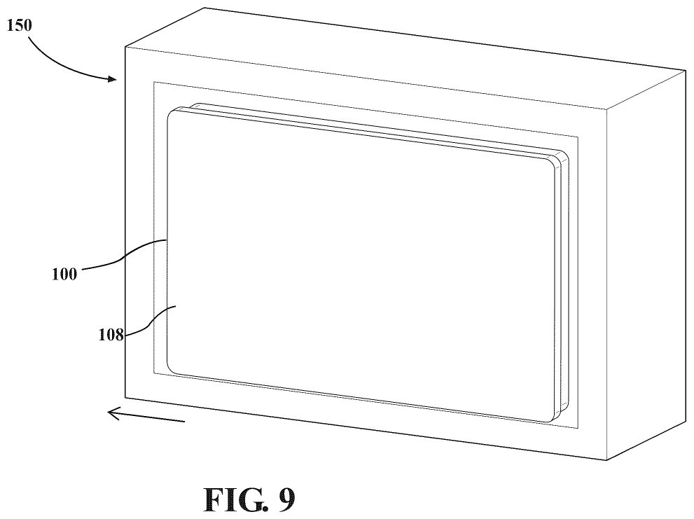

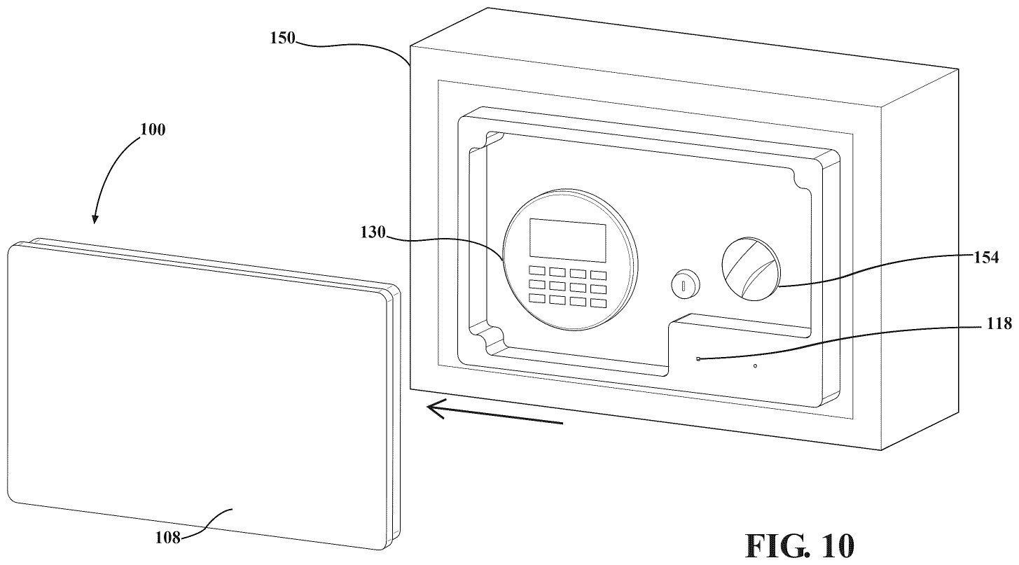

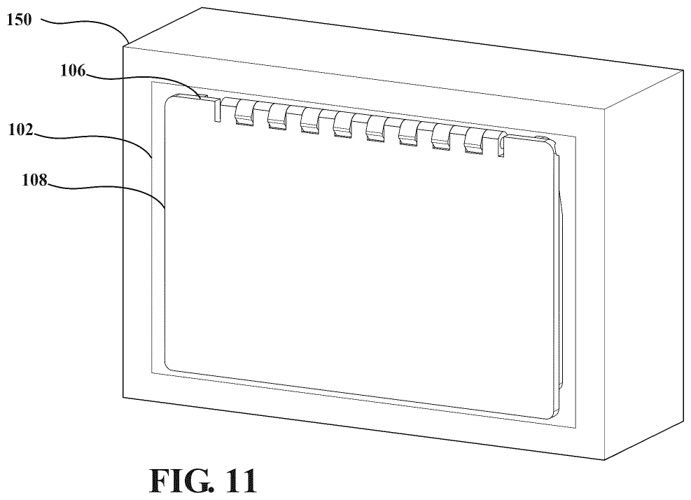

With reference to FIGS. 1-12, the protective device 100 may be configured to militate against unauthorized access to and tampering with an object 150. The protective device 100 may include a frame 102, a cover 108, a sensor 114, and a notification mechanism 118. The frame 102 may be configured to surround an access control 130 on the object 150. The cover 108 may be movably connected to the frame 102 via a hinge 106, as shown in FIGS. 10 and 11. The sensor 114 may be coupled to the frame 102. The sensor 114 may include a sensor magnet 116, which may be coupled to the cover 108. The notification mechanism 118 may be in electronic communication with the sensor 114. In certain embodiments, such as shown in FIGS. 8 and 9, the cover 108 may be slidably coupled with the object such that the cover 108 may be slid off the object 150 in a horizontal and/or a vertical direction. The cover 108 may be further included to cover an access knob 154 of the object 150. It is contemplated that the object 150 may include multiple devices including those such as a safe, gate access, thermostat, lock box, garage, and other appropriately desired accessible spaces.

In certain embodiments, the protective device 100 may also be implemented on a transportation vehicles, such as a semi-trailer or a truck box, where the protective device 100 may be installed over a latch, closure mechanism or an access control 130 to provide security monitoring. In such application, the frame 102 may be configured to surround the latch, the closure mechanism or access control, while the cover 108 provides selective access. The sensor 114 may detect any movement of the cover 108, thereby providing an additional layer of security for commercial transportation and other applications.

The frame 102 may include a singular (e.g., cylindrical) sidewall 104 or may include a plurality of sidewalls 104. A sidewall 104 of the frame 102 may include a first sidewall, a second sidewall, a third sidewall, and a fourth sidewall. Each sidewall 104 may be connected to the frame 102 to define the protective device 100. The frame 102 may be made from a material that is resistant to tampering, such as a unauthorized physical interference, manipulation attempt, or attempted removal directed at the access control 130 itself or the protective device 100 to ensure that the access control 130 is well-protected against physical interference. Tampering may further include an effort to remove, disable, or circumvent the frame 102, cover 108, or locking mechanism 124 or an attempt at force entry or damage, as would be understood by someone of ordinary skill in the art.

The frame 102 of the protective device 100 may have a transparent component. The locking mechanism 124 may include one or more screws, which may provide a secure and stable attachment of the frame 102 to the object 150. The frame 102 may be rectangular in shape, in a certain embodiment. Alternatively, the frame 102 may be circular in shape or any polygonal shape. One of ordinary skill in the art may select a suitable shape to configure the frame 102 within the scope of the present disclosure.

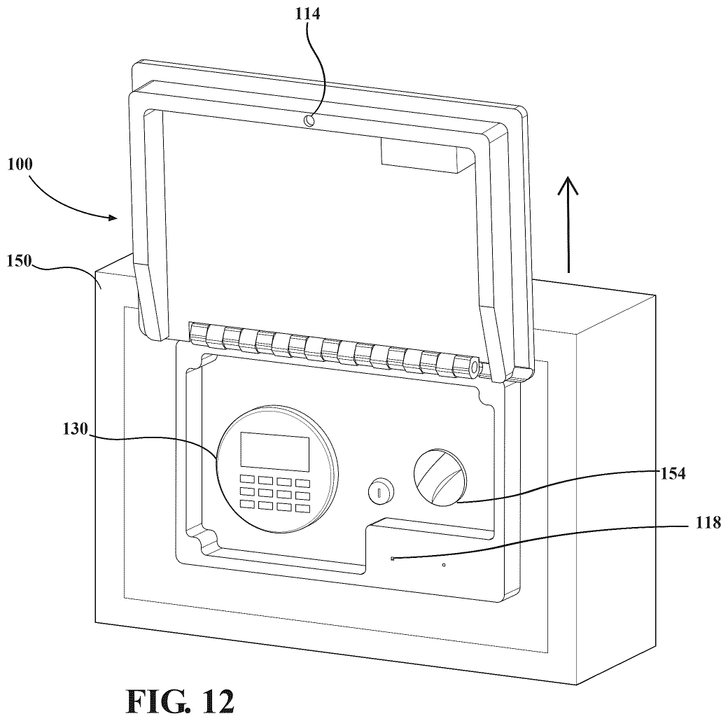

The cover 108 may be configured to allow selective access to the access control 130. Such as shown in FIGS. 11 and 12, the cover 108 may be connected to the frame 102 via a hinge 106. The cover 108 may be connected to the frame 102 via various types of hinges 106 configured to pivot the cover 108 with respect to the frame 102. The hinge 106 may be tamper resistant. One of ordinary skill in the art may select a suitable hinge 106 within the scope of the present disclosure. The cover 108 may be movable between an open position and a closed position. The open position may be configured to expose the access control 130 of the object 150, allowing for authorized use. The closed position may be configured to cover the access control 130 protecting the access control 130 from unauthorized access. The cover 108 may also be transparent to allow the user to see the access control 130 through the cover 108. Alternatively, the cover 108 may be opaque to protect the visibility of the access control 130. One of ordinary skill in the art may select a suitable cover 108 within the scope of the present disclosure.

Alternatively, in certain embodiments, such as shown in FIGS. 8 and 9, the cover 108 may be a sliding cover configured to be coupled to the frame 102 and provide selective access to the access control 130 of the cover 108. More specifically, the cover 108 may be configured to slide in a vertical direction relative to the frame 102 to provide exposure of the access control 130. The cover 108 may also be configured to slide in a horizontal direction relative to the frame 102 to provide exposure of the access control 130. Advantageously, the sliding cover may militate against the need for the hinge 106 and requires the user to slide the cover 108 in the open position or the closed position. The protective device 100 may further send the alert to the user when the sliding cover is moving or moved to the open position. One of ordinary skill in the art may select a suitable configuration for movement of the cover 108 relative to the frame 102 within the scope of the present disclosure.

The sensor 114 may include a motion detection sensor, configured to detect the movement of the cover 108 between the open position and the closed position. The sensor 114 may be in communication with the sensor magnet 116, such as shown in FIG. 7. The sensor magnet 116 may be coupled to the cover 108 and may be in electronic communication with the sensor 114. The sensor magnet 116 may be configured to activate the sensor 114 from a predetermined distance as the cover 108 moves between either the open position or the closed position. The sensor magnet 116 may activate the sensor 114 when the cover 108 is moved. The sensor 114 may be configured to transmit a signal to the notification mechanism 118. Alternatively, the sensor magnet 116 may communicate to the sensor 114 as soon as the cover 108 is moved to the open position and thus activate a sounding alarm while simultaneously communicating with the notification mechanism 118 that the cover 108 is in the open position. One of ordinary skill in the art may select a suitable configuration for the sensor 114 within the scope of the present disclosure.

Alternatively, the sensor 114 may not include the sensor magnet 116. Rather, the sensor 114 may be directly coupled to the cover 108 and configured to detect movement of the cover 108 from the closed position to the open position. The sensor 114 may be a motion detection sensor that is configured to detect the movement and electronically communicate with the user device 119 to alert the user that the cover 108 of the protective device 100 is moved to the open position. Advantageously, this militates against the need to provide both the sensor 114 and the sensor magnet 116 and allows the sensor 114 to function as the sole motion detection sensor, providing a simple, yet effective protective device 100. For example, the sensor may include a sensor selected from a group consisting of a motion detection sensor, a magnetic proximity sensor, a hall effect sensor, an optical sensor, a mechanical switch sensor, and combinations thereof and configured to detect the movement of the cover when the cover is moved a predetermined distance. In particular, the sensor may not include the sensor magnet and may be directly coupled to the cover and configured to detect movement of the cover from the closed position to the open position. The sensor may include other proximity sensors, optical sensors, or mechanical switches to detect a physical movement or position change of the cover 108 relative to the frame 102.

The notification mechanism 118 may be in electronic communication with the sensor 114. The notification mechanism 118 may include a wireless transmitter. The notification mechanism 118 may be configured to send a notification to a user device 119 when the cover 108 is moved to the open position. The user device 119 may include an appropriately desired user device. The notification sent to the user device 119 may include a time at which the cover 108 is moved to the open position. This may enable precise monitoring of the access control 130. The notification mechanism 118 may further be configured to send an additional alert if the cover 108 remains open beyond a predetermined time period. This may ensure that the access control 130 is not left unprotected for an extended period of time. Additionally, the notification mechanism 118 may be configured to electronically communicate with multiple user devices, allowing multiple users to be alerted simultaneously in the event of unauthorized access. The notification mechanism 118 may include customization options for alert types and preferences, allowing users to tailor the notifications to their specific needs.

The notification mechanism 118 may be adapted to utilize various communication protocols such as Wi-Fi, Bluetooth, or cellular networks, depending on the specific requirements of the security system in place. The user device 119 receiving the notifications may include not only cell phones but also tablets, computers, integrated home automation systems, central control panels, and any receiving device configured to electronically communicate with the sensor 114 for receiving the alert, such as a commercial alarm system. The flexibility in configuring the notification mechanism 118 allows the notification mechanism 118 to be customized to meet the unique security needs of different environments, from residential to commercial settings. One of ordinary skill in the art may also select different types of sensors, magnets, or additional security features as desired to enhance the overall functionality and responsiveness of the protective device 100.

The protective device 100 may further include a locking mechanism 124. Both the frame 102 and the cover 108 may be removably coupled to the locking mechanism 124 to secure the cover 108 to the frame 102 when the cover is in the closed position. Advantageously, the locking mechanism 124 may add an additional layer of security to the protective device 100. The protective device 100 may be configured to notify the user when the locking mechanism 124 is tampered with via the notification mechanism 118.

In certain embodiments, when the cover 108 remains open for a predetermined period and following a proper depression of a code of the access control 130, this would suggest that an authorized user is legitimately accessing the protected object or area, rather than an unauthorized individual attempting to tamper with the system. As such, the notification mechanism 118 may send a signal to the user device 119 of an authorized access. Such notification may allow protective device 100 to reduce a false alarms when an authorized user is properly accessing the protective device 100 while maintaining protection against an unauthorized access. In certain embodiments the authorized access confirmation may be electronically communicated to an appropriate security personnel or system administrators.

The locking mechanism 124 may be designed in various forms to enhance security. For instance, the locking mechanism 124 may include a key lock mechanism, a combination lock mechanism, or even incorporate advanced technologies such as a biometric lock that requires fingerprint identification or facial recognition to unlock. Additionally, the locking mechanism 124 may be integrated with an electronic monitoring system that alerts the user if tampered with or if incorrect attempts are made to unlock. This adaptability allows the protective device 100 to be tailored to specific security needs and threat levels, making it suitable for a wide range of applications from residential safes to high-security commercial environments. One of ordinary skill in the art may also select different materials, integration methods, or additional security sensors as desired to customize the locking mechanism 124 according to specific user requirements and contexts.

With reference now to FIG. 13, a method 200 of safeguarding an access control 130 of a device is depicted therein. In a first step 202 a method includes providing a device having a body defining a container, the body including the access control 130 disposed on an outer portion of the body. In a second step 204 the method may include providing a cover for the access control 130; and in a third step 206, a method may include sending a notification to a user device when the cover is moved from a closed position to an open position.

Advantageously, the protective device 100 and method 200 shield an access control 130 of an object 150 from tampering and unauthorized access, before an unauthorized user may gain access to the contents of the object 150, such as a safe, or other access controlled space. Desirably, the protective device 100 also enhances user interaction by providing notifications to the user when the access control 130 is exposed, offering an alert to an access status. The protective device 100 may provide the notification to the user when the cover 108 is moved from the closed position, while the cover 108 may allow for selective access to the access control 130. Desirably, the protective device 100 may be easily installed as the cover 108 may be magnetically attached, while the sensor 114 may notify the user of any exposure of the access control 130. Such features significantly militate against the risks of unauthorized entry, thereby offering a superior security solution that maintains convenience and ease of use for authorized users.

### EXAMPLES

Example embodiments of the present technology are provided with reference to the several figures enclosed herewith.

The protective device may be implemented on a controlled access area or object. The area or object may be equipped with a digital access control 130. The protective device, as described herein, may be installed such that the frame surrounds of the access control 130, or an entirety of the area or device. The frame may be constructed from a high-strength, tamper-resistant material that resists attempts at forced entry or damage. When the cover is moved to the open position, the sensor magnet may detect the change in proximity of the sensor magnet and the sensor magnet coupled to the cover may electronically communicate with the sensor of the protective device. In turn, the sensor may electronically communicate with the notification mechanism which may send a notification to the user that the access control 130 of the object 150 may be tampered with.

The notification mechanism may be configured to send an immediate alert to the a cellphone of a security manager and the central security system of the retail store. This alert may include the time the access control was exposed, providing security monitoring. This may enhance the physical security and integrate existing security protocol, offering a security solution to monitor and record access.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. Equivalent changes, modifications and variations of some embodiments, materials, compositions and methods can be made within the scope of the present technology, with substantially similar results.

What is claimed is:

1. A protective device for safeguarding an access control of an object, comprising:
a frame having a sidewall configured to surround the access control of the object;
a cover movably connected to the frame; and
a sensor coupled to the frame, the sensor configured to detect a movement of the cover, the sensor in communication with a notification mechanism, wherein the notification mechanism is configured to send a notification to a user device when the cover is moved.

2. The protective device of claim 1, wherein the cover is movable between an open position and a closed position, and the sensor is configured to detect a movement of the cover from the closed position to the open position.

3. The protective device of claim 1, wherein the cover is pivotably connected to the frame.

4. The protective device of claim 1, wherein the cover includes a transparent portion to allow the access control to be visible therethrough.

5. The protective device of claim 1, wherein the cover includes a sliding cover.

6. The protective device of claim 1, wherein the sensor includes a sensor selected from a group consisting of a motion detection sensor, a magnetic proximity sensor, a hall effect sensor, an optical sensor, a mechanical switch sensor, and combinations thereof and configured to detect the movement of the cover when the cover is moved a predetermined distance.

7. The protective device of claim 1, wherein the notification mechanism includes a wireless transmitter.

8. The protective device of claim 1, wherein the notification mechanism is configured to send an additional notification if the cover remains open beyond a predetermined period of time.

9. The protective device of claim 1, wherein the notification mechanism is configured to electronically communicate with multiple user devices.

10. The protective device of claim 1, wherein the notification sent to the user device includes a time at which the cover is moved.

11. The protective device of claim 1, further comprising a locking mechanism configured to lock a position of the cover relative to the frame.

12. A protective cover system, comprising:
a body defining a container including an access control of an object comprising:
a frame having a sidewall configured to surround the access control of the object;
a cover movably connected to the frame; and
a sensor coupled to the frame, the sensor configured to detect a movement of the cover, the sensor in communication with a notification mechanism, wherein the notification mechanism is configured to send a notification to a user device when the cover is moved.

13. The protective cover system of claim 12, wherein the cover includes a transparent portion to allow the access control to be visible therethrough.

14. The protective cover system of claim 12, wherein the cover is configured to surround the access control and an opening access to the body.

15. The protective cover system of claim 12, wherein the cover is shaped and sized to dimensions of the access control.

16. A method of safeguarding an access control of a object, comprising:
providing a device having a frame having a sidewall configured to surround the access control of the object;
a cover movably connected to the frame; and
a sensor coupled to the frame, the sensor configured to detect a movement of the cover, the sensor in communication with a notification mechanism,
wherein the notification mechanism is configured to send a notification to a user device when the cover is moved; and
sending a notification when the cover is moved from a closed position to an open position.

17. The method of claim 16, further comprising sending a first notification when the cover is in the open position.

18. The method of claim 17, further comprising sending a second notification when the cover is in the closed position.

19. The method of claim 18, further comprising sending a third notification when the cover remains open for a predetermined period of time based on a proper depression of a keypad code to indicate that access was authorized.

20. The method of claim 16, further comprising sending a notification upon detecting tampering from an outside portion of the cover.
